(19) United States
(12) Patent Application Publication
(10) Pub. No.: US 2009/0261477 A1
(43) Pub. Date: Oct. 22, 2009

(54) Semiconductor device and method of manufacturing the same

(76) Inventor: Ji-Ho Hong, Gyeonggi-do (KR)

Correspondence Address: SHERR & VAUGHN, PLLC, 620 HERNDON PARKWAY, SUITE 320, HERNDON, VA, 20170, US

(21) Appl. No.: 11/953,607

(22) Filed: Dec. 10, 2007

(30) Foreign Application Priority Data
Dec. 27, 2006 (KR) 10-2006-0134815

(51) Int. Cl. H01L 23/535; H01L 21/768

(52) U.S. Cl. 257/773; 438/653; 438/652; 257/E21.584; 257/E21.585; 257/E23.168

(57) ABSTRACT

A method of manufacturing a semiconductor device including a trench and a contact hole filled with a copper line, a diffusion barrier layer formed in inner walls of the trench and the contact hole, and a seed-copper layer formed on and/or over the diffusion barrier layer. The surface roughness of the seed-copper layer can be reduced by performing a plasma process thereon.

The present application claims priority under 35 U.S.C. 119 and 35 U.S.C. 365 to Korean Patent Application No. 10-2006-0134815 (filed on Dec. 27, 2006), which is hereby incorporated by reference in its entirety.

### BACKGROUND

Higher speed and integration of semiconductor devices are rapidly progressing, and consequently, the sizes of transistors have become smaller. As the degree of integration in transistors increases, lines of semiconductor devices may become more miniaturized, and thus, a signal applied to a line may be delayed or distorted, such that a high speed operation of a semiconductor device can be interrupted.

Consequently, a metal line formed of copper may be considered since copper has a higher electro-migration (EM) tolerance and a lower resistance than aluminum or aluminum alloys. Copper has also been widely used for a line material of a semiconductor device until recently. Although a copper layer may be formed first and then etched to form a cooper line, the etching of the cooper layer may be difficult and the surface of the cooper layer may become oxidized. Consequently, a damascene process may be used to resolve such problems during formation of the copper line.

Particularly, a damascene process can be used to form a trench and a contact hole in an insulating layer, deposit a copper layer on and/or over the insulating layer to fill the trench and the contact hole, and then planarizes the copper layer through a chemical mechanical polishing (CMP) process to form a copper line inside the trench and contact hole. Research for a resistance properties between a seed-copper layer and copper deposited thereon, and also electrical property improvement of a semiconductor device may be required in the damascene process.

### SUMMARY

Embodiments relate to a semiconductor device having improved yield and electrical properties based on a resistance property of copper with respect to the surface roughness of a seed-copper layer during formation of a line.

Embodiments relate to a semiconductor device having improved yield and electrical properties achievable by adjusting the surface roughness with respect to a seed-copper layer during a damascene process when forming a line.

Embodiments relate to a semiconductor device having improved yield and electrical properties achievable by reducing the surface roughness of a seed-copper layer through a plasma process on the seed-copper layer during a damascene process when forming a line.

Embodiments relate to a method of manufacturing a semiconductor device that can include at least one of the following steps: forming a trench and a contact hole in a semiconductor substrate; forming a diffusion barrier layer in inner walls of the trench and the contact hole; forming a seed-copper layer over the diffusion barrier layer; and then reducing a surface roughness of the seed-copper layer.

Embodiments relate to a method of manufacturing a semiconductor device that can include at least one of the following steps: forming a trench and a contact hole in a semiconductor substrate; forming a first conductor layer in inner walls of at least one of the trench and the contact hole; adjusting a surface roughness of the first conductor layer; and then forming a second conductor layer over the first conductor layer.

Embodiments relate to a semiconductor device that can include a trench and a contact hole formed in a semiconductor substrate; a first conductor layer formed in inner walls of at least one of the trench and the contact hole; and a second conductor layer formed over the first conductor layer. In accordance with embodiments, the root mean square value of a surface roughness of the first conductor is below 1.0.

### DRAWINGS

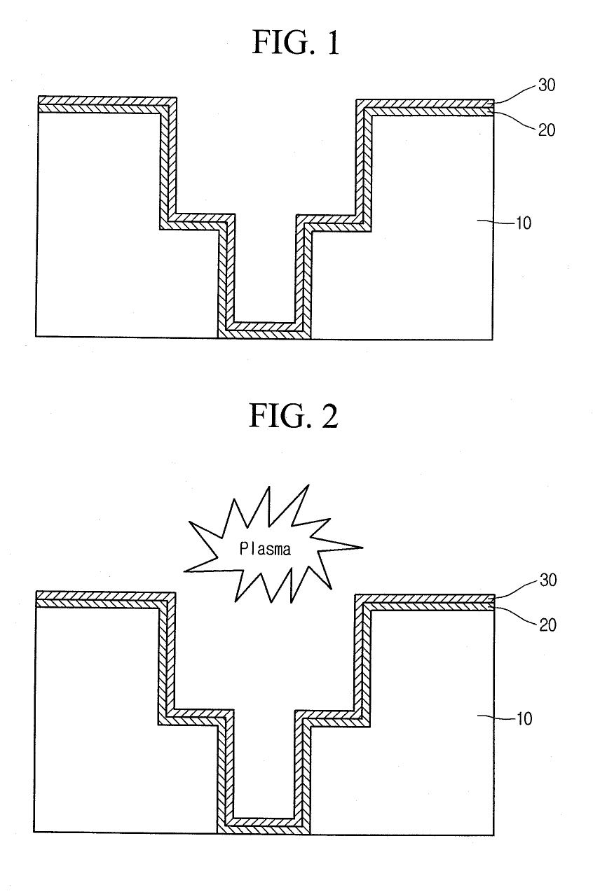

Example FIG. 1 illustrates a diffusion barrier layer and a seed-copper layer in inner walls of a contact hole and a trench of an interlayer insulating layer, in accordance with embodiments.

Example FIG. 2 illustrates a plasma process, in accordance with embodiments.

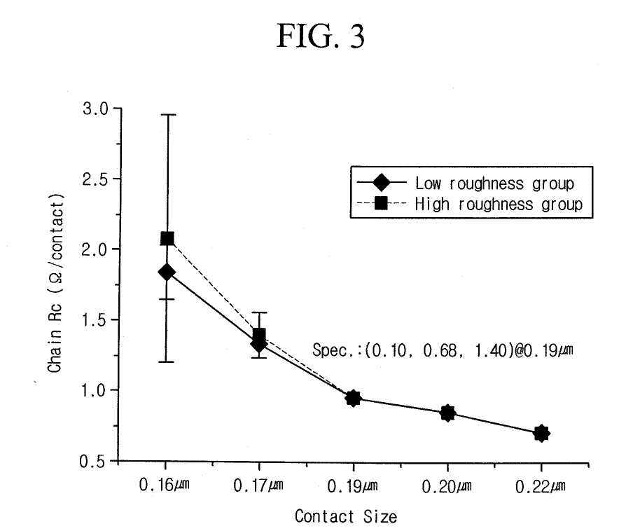

Example FIG. 3 illustrates a graph of an average resistance value with distribution by the contact size, in accordance with embodiments.

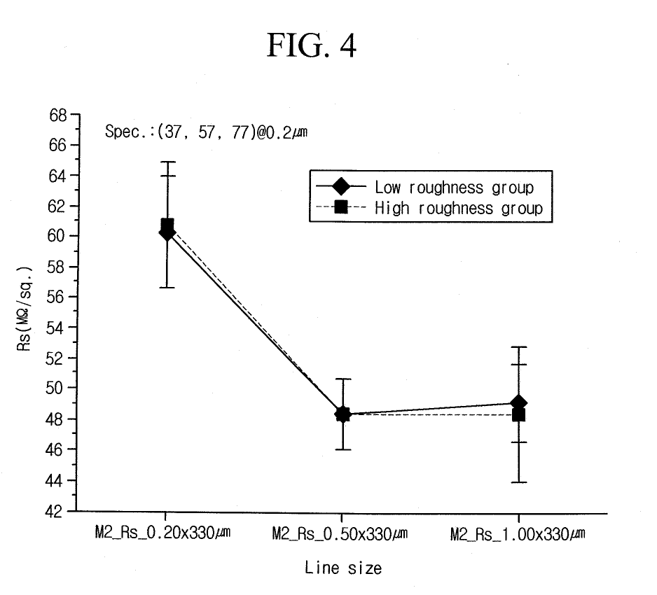

Example FIG. 4 illustrates a graph of an average resistance value with distribution by the line size, in accordance with embodiments.

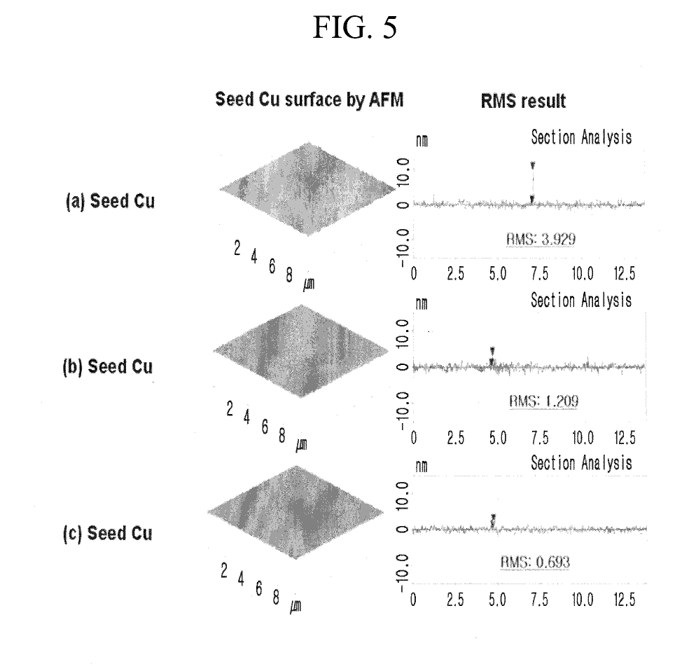

Example FIG. 5 illustrates s a view of the surface roughness value of a seed-copper layer measured by atomic force microscopy (AFM), in accordance with embodiments.

### DESCRIPTION

In the following description, it will be understood that when a layer (or film) is referred to as being ‘on/above/over/upper’ another layer or substrate, it can be directly on/above/over/upper the other layer or substrate, or intervening layers may also be present. Further, it will be understood that when a layer is referred to as being ‘down/below/under/lower’ another layer, it can be directly down/below/under/lower the other layer, and one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the embodiment.

In accordance with embodiments, a conductor line can be formed in inner walls of at least one of a trench and a contact hole of a semiconductor device during a damascene process. A first conductor layer and a second conductor layer can then be sequentially formed in order to pattern a conductor line. The first and second conductor layers may be formed of the same material.

A metal material such as copper (Cu) can then be used as the conductor line. The first conductor layer can serve as a seed conductor while the second conductor layer can serve as a conductor line.

A first interlayer insulating layer for insulation between metal layers can be formed on and/or over a base interlayer insulating layer having a bottom metal line. If a copper line is formed using a dual damascene process, an etch stop layer can be formed on and/or over the first interlayer insulating layer. A second interlayer insulating layer can then be formed on and/or over the first interlayer insulating layer. The etch stop layer can be omitted in accordance with embodiments. After formation of a contact hole in the first interlayer insulating layer through a dual damascene process, a trench can be formed in the second interlayer insulating layer. Alternatively, after the trench is formed in the second interlayer insulating layer, the contact hole can be formed in the first interlayer insulating layer. A single damascene process may be used in accordance with embodiments.

As illustrated in example FIG. 1, semiconductor substrate 10 may include a contact hole and a trench formed therein. Diffusion barrier layer 20 can be formed on and/or over semiconductor substrate 10 including inside the inner walls of the contact hole and the trench in order to prevent copper from spreading toward an adjacent insulating layer. Diffusion barrier layer 20 may be formed of one selected from the group consisting of Ti, TiN, Ta, and TaN. Seed-copper layer 30 can then be formed on and/or over diffusion barrier layer 20.

As illustrated in example FIG. 2, a plasma process can then be performed on seed-copper layer 30 to improve the surface roughness of seed-copper layer 30. The surface roughness of seed-copper layer 30 can be improved through plasma having NH₃.

Related to the improvement of the surface roughness in seed copper layer 30, testing was conducting in accordance with embodiments for demonstrating a correlation between the surface roughness of seed-copper layer 30 and the resistance of copper deposited on and/or over seed-copper layer 30. After a 0.13 μm copper dual damascene process is performed on two groups having respectively different surface roughness and processed with a seed-copper layer forming process, the results of the surface resistance Rs and contact resistance Rc are illustrated in example FIGS. 3 and 4. As illustrated in example FIG. 3 illustrates an average resistance value with distribution by the contact size while example FIG. 4 illustrates an average resistance value with distribution by the line size.

A low roughness group with a low surface roughness shown in a solid line has a root-mean-square (RMS) value of below 1.0, and a high roughness group with a high surface roughness shown in a dotted line has a root-mean-square value of over 3.5. As illustrated in example FIGS. 3 and 4, according to surface roughness values in the seed-copper layer, the two groups have respectively different values of the surface resistance Rs and contact resistance Rc, and have average resistance values with great differences especially in the small size pattern.

During a copper damascene process based on the above testing results, the yield increase or performance improvement in the semiconductor device can be obtained by appropriately improving or adjusting the surface roughness of the seed-copper layer, and it is desirable that the seed-copper layer has the surface roughness with a RMS value of below 1.0.

Accordingly, a plasma process for improving the surface roughness of the seed-copper layer sets a RMS value of the surface roughness below 1.0. For this, for example, in a case where a plasma process including NH3 is performed, the plasma process is performed during several to several hundreds of seconds with NH3 gas including a flux of 70 to 80 scccm, a pressure of 4.0 to 4.5 Torr, and a heating temperature of 350 to 450° C. in a nitrogen gas atmosphere of 4500 to 5500 sccm in a plasma enhanced chemical vapor deposition (PECVD) chamber. As a processing time increase, a RMS value of the surface roughness decreases.

As illustrated in example FIG. 5, an atomic force microscopy (AFM) morphology and a RMS value of over 3.5 for the seed-copper layer surface can be achieved. An ARM morphology and a RMS value of the seed-copper layer surface after performing a plasma process on the initial seed-copper layer surface during 10 seconds within the plasma process conditions are shown in (b). An ARM morphology and a RMS value of the seed-copper layer surface after performing a plasma process on the initial seed-copper layer surface during 15 seconds within the plasma process conditions are shown in (b).

Accordingly, in a case where a surface roughness value of the initial seed-copper layer before the plasma process is over 3.5, if the plasma process is performed during at least 15 seconds, the surface roughness for the seed-copper layer may have a RMS value of below 1.0. For example, when a the plasma process is performed during 15 seconds with NH3 gas including a flux of 75 scccm, a pressure of 4.2 Torr, and a heating temperature of 400° C. in a nitrogen gas atmosphere of 5000 sccm in a PECVD chamber, a RMS value of the surface roughness for the seed-copper layer becomes below 1.0.

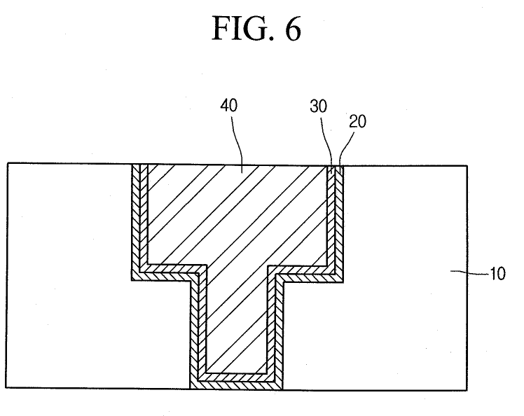

As illustrated in example FIG. 6, after reducing the surface roughness of seed-copper layer 30 by performing a plasma process thereon, copper can then be deposited on and/or over seed-copper layer 30 using an electroplating method in order to increase the overall yield and enhance the electrical properties of the semiconductor device. A chemical mechanical polishing (CMP) process can then be performed on the deposited copper for planarization.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed:

1. A method comprising:
forming a trench and a contact hole in a semiconductor substrate;
forming a diffusion barrier layer in inner walls of the trench and the contact hole;
forming a seed-copper layer over the diffusion barrier layer; and then
reducing a surface roughness of the seed-copper layer.

2. The method of claim 1, wherein reducing the surface roughness of the seed-copper layer comprises performing a plasma process on the seed-copper layer.

3. The method of claim 2, wherein reducing the surface roughness of the seed-copper layer comprises setting a root mean square value of the surface roughness of the seed-copper layer below 1.0.

4. The method of claim 2, wherein the plasma process uses plasma including NH₃ gas.

5. The method of claim 2, wherein the plasma process is performed using NH₃ gas including a flux of between 70 to 80 scccm, a pressure of between 4.0 to 4.5 Torr, and a temperature of between 350 to 450° C. in a nitrogen gas atmosphere of 4500 to 5500 sccm.

6. The method of claim 2, wherein the plasma process is performed for at least 15 seconds using NH₃ gas including a flux of 75 scccm, a pressure of 4.2 Torr, and a temperature of 400° C. in a nitrogen gas atmosphere of 5000 sccm.

7. The method according to claim 1, further comprising depositing a copper layer over the seed-copper layer after reducing the surface roughness of the seed-copper layer.

8. A method comprising:
forming a trench and a contact hole in a semiconductor substrate;
forming a first conductor layer in inner walls of at least one of the trench and the contact hole;
adjusting a surface roughness of the first conductor layer; and then
forming a second conductor layer over the first conductor layer.

9. The method of claim 8, wherein the first conductor layer comprises a seed-conductor layer.

10. The method of claim 8, wherein the second conductor layer comprises a conductor line.

11. The method of claim 8, wherein the first conductor layer and the second conductor layer are formed of the same material.

12. The method of claim 11, wherein the same material comprises a metal material.

13. The method according to claim 12, wherein the metal material comprises copper.

14. The method of claim 8, wherein the first conductor layer and the second conductor layers are formed of a metal material.

15. The method of claim 8, wherein the first conductor layer and the second conductor layers are formed of copper.

16. The method of claim 8, wherein the surface roughness of the first conductor layer is adjusted by a plasma process.

17. The method of claim 8, wherein adjusting the surface roughness of the first conductor layer comprises reducing the surface roughness of the first conductor layer.

18. The method of claim 8, further comprising setting a root mean square value of the surface roughness of the first conductor is below 1.0.

19. The method of claim 8, wherein adjusting the surface roughness of the first conductor layer comprises performing a plasma process including NH₃ gas on the first conductor layer.

20. An apparatus comprising:
a trench and a contact hole formed in a semiconductor substrate;
a first conductor layer formed in inner walls of at least one of the trench and the contact hole; and
a second conductor layer formed over the first conductor layer,
wherein the root mean square value of a surface roughness of the first conductor is below 1.0.
